(19) United States
(12) Patent Application Publication
(10) Pub. No.: US 2019/0378794 A1
(43) Pub. Date: Dec. 12, 2019

(54) BANDGAP REFERENCE DIODE USING THIN FILM TRANSISTORS

(71) Applicant: Intel Corporation, Santa Clara, CA (US)

(72) Inventors: Abhishek A. Sharma, Hillsboro, OR (US); Gilbert Dewey, Hillsboro, OR (US); Willy Rachmady, Beaverton, OR (US); Van Le, Beaverton, OR (US)

(73) Assignee: Intel Corporation, Santa Clara, CA (US)

(21) Appl. No.: 16/001,083

(22) Filed: Jun. 6, 2018

(51) Int. Cl. H01L 23/522; G05F 3/20; H01L 23/532; H01L 21/285

(52) U.S. Cl. CPC H01L 23/5226; G05F 3/20; G01K 7/01; H01L 23/53214; H01L 21/28556; H01L 23/5329

(57) ABSTRACT

Bandgap reference diodes and bandgap reference circuits are used to provide voltage references for a wide range of integrated circuit (IC) functions. Many bandgap reference diodes are fabricated directly on the substrate surface during the front-end-of-line (FEOL), and require a significant substrate footprint. Embodiments described herein are directed to bandgap reference diodes comprised of thin film transistors and methods of forming the same. The bandgap reference diodes described herein need not be fabricated during the FEOL, and can instead be formed during the back-end-of-line (BEOL) metallization workflow, freeing the substrate surface for other devices.

### TECHNICAL FIELD

The present disclosure generally relates to semiconductor devices. More specifically, the present disclosure relates to bandgap reference diodes.

### BACKGROUND

Bandgap reference diodes and bandgap reference circuits (also called voltage reference circuits) are used to a great extent in analog, digital and mixed analog-digital circuits to provide voltage references for various integrated circuit (IC) functions. A bandgap voltage reference is a temperature independent voltage reference which produces a fixed, constant voltage regardless of power supply variations, temperature changes and circuit loading from a device. The reference voltage output from bandgap reference diodes can be used, for example, in an analog-to-digital converter to accurately quantify an input, in a digital-to-analog converter to define the output for a full-scale range, and in a power supply to accurately control a supplied voltage level.

Bandgap reference diodes operate on the principle of the addition of two voltages having opposite temperature responses. One of the voltages includes a positive temperature coefficient, meaning that the voltage rises proportionately with absolute temperature, and is often referred to as a proportional to absolute temperature (PTAT) voltage. The other voltage includes a negative temperature coefficient, meaning that the voltage falls as the temperature rises, and is often referred to as a complementary to absolute temperature (CTAT) voltage. As the temperature coefficients of these two voltages are opposite, the PTAT voltage and the CTAT voltage can be combined to provide a voltage which is insensitive to temperature variations. In other words, the PTAT voltage and the CTAT voltage can be combined such that the temperature coefficient of the sum is nearly zero.

Bandgap reference circuits generally include two diode-connected transistors operating at different emitter current densities, and resistors for summing the PTAT voltage and the CTAT voltage. The ideal bandgap reference circuit produces a reference voltage that is constant regardless of process, voltage, and temperature variations. Accordingly, bandgap reference circuits which are accurate and stable versus temperature, supply voltage and manufacturing variations are highly desirable.

### BRIEF DESCRIPTION OF THE FIGURES

Reference will now be made to the accompanying drawings, which are not necessarily drawn to scale, and wherein:

FIG. 1 shows a semiconductor device after the fabrication of a bandgap reference diode using thin film transistors, in accordance with one or more example embodiments of the disclosure.

FIG. 2 shows an alternative semiconductor device after the fabrication of a bandgap reference diode using thin film transistors, in accordance with one or more example embodiments of the disclosure.

FIG. 3 shows a semiconductor device during the fabrication of a bandgap reference diode using thin film transistors, in accordance with one or more example embodiments of the disclosure.

FIG. 4 shows a semiconductor device during the fabrication of a bandgap reference diode using thin film transistors, in accordance with one or more example embodiments of the disclosure.

FIG. 5 shows a semiconductor device during the fabrication of a bandgap reference diode using thin film transistors, in accordance with one or more example embodiments of the disclosure.

FIG. 6 shows a semiconductor device during the fabrication of a bandgap reference diode using thin film transistors, in accordance with one or more example embodiments of the disclosure.

FIG. 7 shows a diagram of an example process flow for the fabrication of a nanoribbon transistor, in accordance with example embodiments of the disclosure.

FIG. 8 depicts an example of a system, in accordance with one or more embodiments of the disclosure.

### DETAILED DESCRIPTION

Embodiments of the disclosure are described more fully hereinafter with reference to the accompanying drawings, in which example embodiments of the disclosure are shown. This disclosure may, however, be embodied in many different forms and should not be construed as limited to the example embodiments set forth herein; rather, these embodiments are provided so that this disclosure will be thorough and complete, and will fully convey the scope of the disclosure to those skilled in the art. Like numbers refer to like, but not necessarily the same or identical, elements throughout.

The following embodiments are described in sufficient detail to enable at least those skilled in the art to understand and use the disclosure. It is to be understood that other embodiments would be evident based on the present disclosure and that process, mechanical, material, dimensional, process equipment, and parametric changes may be made without departing from the scope of the present disclosure.

In the following description, numerous specific details are given to provide a thorough understanding of various embodiments of the disclosure. However, it will be apparent that the disclosure may be practiced without these specific details. In order to avoid obscuring the present disclosure, some well-known system configurations and process steps may not be disclosed in full detail. Likewise, the drawings showing embodiments of the disclosure are semi-diagrammatic and not to scale and, particularly, some of the dimensions may be exaggerated in the drawings for the clarity of presentation. In addition, where multiple embodiments are disclosed and described as having some features in common, for clarity and ease of illustration, description, and comprehension thereof, similar and like features will ordinarily be described with like reference numerals even if the features are not identical.

The term “horizontal” as used herein may be defined as a direction parallel to a plane or surface (for example, surface of a substrate), regardless of its orientation. The term “vertical,” as used herein, may refer to a direction orthogonal to the horizontal direction as just described. Terms, such as “on,” “above,” “below,” “bottom,” “top,” “side” (as in “sidewall”), “higher,” “lower,” “upper,” “over,” and “under,” may be referenced with respect to a horizontal plane, where the horizontal plane can include an x-y plane, a x-z plane, or a y-z plane, as the case may be. The terms “on,” “over,” “above,” “higher,” “positioned on,” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary elements at the interface between the two elements. The term “processing” as used herein includes deposition of material or photoresist, patterning, exposure, development, etching, cleaning, ablating, polishing, and/or removal of the material or photoresist as required in formation of a described structure.

“An embodiment,” “various embodiments,” and the like indicate embodiment(s) so described may include particular features, structures, or characteristics, but not every embodiment necessarily includes the particular features, structures, or characteristics. Some embodiments may have some, all, or none of the features described for other embodiments. “First,” “second,” “third,” and the like describe a common object and indicate different instances of like objects are being referred to. Such adjectives do not imply objects so described must be in a given sequence, either temporally, spatially, in ranking, or in any other manner “Connected” may indicate elements are in direct physical or electrical contact with each other and “coupled” may indicate elements co-operate or interact with each other, but they may or may not be in direct physical or electrical contact. Also, while similar or same numbers may be used to designate same or similar parts in different figures, doing so does not mean all figures including similar or same numbers constitute a single or same embodiment.

The terms “perpendicular,” “orthogonal,” “coplanar,” and/or “parallel” may mean substantially perpendicular, orthogonal, coplanar, or parallel, respectively. For example, “perpendicular” can mean perpendicular within ±20, 15, 10, or 5 degrees. Further, the figures shown herein may not have precisely vertical or horizontal edges, but rather may have some finite slope and have surface roughness, as is to be expected for fabricated devices. The terms “about,” “substantially,” “approximately,” and variations thereof, are intended to include a degree of error associated with a measurement of the particular quantity using equipment available at the time of filing the application. For example, “about” can include a range of ±7% or 5%, or 2% of a given value.

The phrase “selective to,” such as, for example, “etching a first element selective to a second element,” means that the first element is etched while the second element serves as an etch stop. The term “conformal,” such as, for example, “forming a conformal layer,” means that the deposited or otherwise formed thickness of the layer is substantially the same on all surfaces, or that the thickness variation is less than 15% of the nominal thickness of the layer.

The terms “epitaxy” and “epitaxial growth” refer to the growth of a crystalline semiconductor material on a surface of another crystalline semiconductor material. During an epitaxial growth, a crystalline overlayer (the semiconductor material being grown) forms on the surface of a seed material (known as the deposition surface). In an epitaxial deposition process, the overlayer can have substantially the same crystalline characteristics as the seed material. For example, an epitaxially grown semiconductor material deposited on a crystalline surface having a Miller indices of {111} can take on a {111} orientation. Epitaxial growth can be selective to forming on a semiconductor surface, and may or may not deposit material on other exposed surfaces, such as a silicon dioxide or silicon nitride surface.

As discussed previously herein, bandgap reference diodes and bandgap reference circuits are used to provide voltage references for a wide range of integrated circuit (IC) functions. There are challenges, however, in designing and fabricating bandgap reference diodes suitable for some advanced process nodes (for example, beyond the 22 nm technology node). Implementing bandgap reference circuits in advanced process nodes is difficult due in part to the greater process variations, limited choice in transistor sizes, and lower supply voltages inherent to these nodes.

One challenge in the design of bandgap reference diodes for advanced process node architectures is the sheer size required for these components. Many bandgap reference diodes are fabricated directly on the substrate surface during the front-end-of-line (FEOL), substantially concurrently with the transistors, capacitors, and resistors which will make up the final device. Moreover, these bandgap reference circuits often include two p-n junctions formed in an n-well which is itself formed by doping a portion of a p-type substrate. Consequently, bandgap reference diodes require a relatively large footprint on the substrate surface. As device components continually shrink to accommodate advanced process node requirements, FEOL bandgap reference diodes represent an increasingly unacceptable area penalty on the substrate surface. In addition, it can also be challenging to integrate bandgap reference diodes with device architectures that do not easily allow for deep well formation processes, such as, for example, when using silicon on insulator (SOI) and wafer bonding.

Turning now to aspects of the present disclosure, various embodiments described herein provide novel designs and fabrication methods for providing bandgap reference diodes using thin film transistors. The use of thin film transistors offers several advantages over conventional reference diodes. For example, the bandgap reference diodes described herein need not be fabricated during the FEOL, and can instead be formed during the back-end-of-line (BEOL) metallization workflow. In other words, rather than being formed on the substrate surface, these bandgap reference diodes include thin film transistors which are formed over one or more of the BEOL metallization layers. Consequently, the bandgap reference diodes described herein do not consume or otherwise require a large substrate footprint, which is at a premium in advanced process nodes. Another advantage in using thin film transistors to provide bandgap reference diodes is a relatively large drain-source voltage (Vds) and high overdrive capability, which allows for these devices to be used in high voltage applications which are not suitable to conventional bandgap reference diodes. Finally, leveraging thin film transistors to provide bandgap reference diodes greatly simplifies the integration of bandgap reference diodes into workflows that do not easily allow for deep well formation processes (for example, when using SOI and wafer bonding).

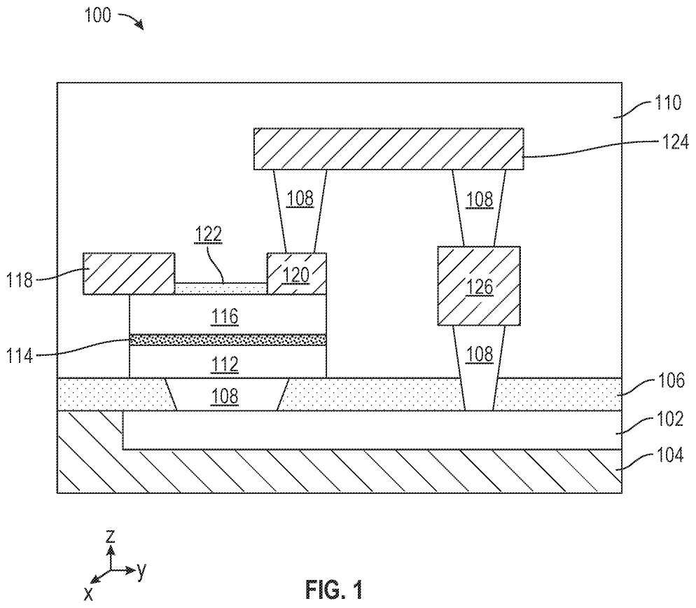

FIG. 1 depicts a cross-sectional view of a semiconductor structure 100 during the fabrication of bandgap reference diodes using thin film transistors in accordance with one or more example embodiments of the disclosure. In one embodiment, the semiconductor structure 100 can include a conductive line 102 (also known as an interconnect or as a metal line) formed in an interlayer dielectric (ILD) 104 of a metallization layer. The metallization layer can be a first metallization layer, or any other metallization layer, of a BEOL workflow. While not depicted, it is understood that the conductive line 102 and the ILD 104 are formed over a substrate following completion of the FEOL. In some embodiments, one or more metallization layers are formed between the first metallization layer and the substrate. The conductive line 102 can be formed using, for example, copper (Cu) or aluminum (Al), although any suitable conductive material can be used. Non-limiting examples of suitable conductive materials for the conductive line 102 include tantalum (Ta), cobalt (Co), nickel (Ni), palladium (Pd), platinum (Pt), gold (Au), silver (Ag), tungsten (W), titanium (Ti), molybdenum (Mo), germanium (Ge), ruthenium (Ru), or any combination of the foregoing.

The conductive line 102 can be formed using known metallization techniques. In one embodiment, the ILD 104 may be patterned using, for example, a wet etch, a dry etch, or a combination thereof, to provide one or more trenches. In one embodiment, these trenches are filled with conductive material to form the conductive line 102. In one embodiment, the conductive material may be overfilled into the trenches, forming overburdens above a surface of the ILD 104. The overburden can be removed using, for example, chemical-mechanical planarization.

The ILD 104 can include any suitable dielectric material, such as, for example, silicon oxides, silicon nitrides, porous silicates, carbon doped oxides, silicon oxynitrides (SiON), spin-on polymers, and low permittivity (low-k) dielectric materials. In one embodiment, low-k dielectric materials can refer to dielectrics having a dielectric constant (permittivity k) lower than the permittivity of silicon dioxide. In one embodiment, the ILD 104 can be deposited or otherwise formed to any desired thickness using physical vapor deposition (PVD), chemical vapor deposition (CVD), plasma-enhanced CVD (PECVD), metal organic chemical vapor deposition (MOCVD), molecular beam epitaxy (MBE), atomic layer deposition (ALD), and/or spin-on dielectrics, and the like.

In one embodiment, the semiconductor structure 100 can include an etch stop layer 106 formed over the conductive line 102 and the ILD 104. The etch stop layer 106 can be made of any suitable material, such as, for example, a low-k dielectric, silicon nitride, SiON, silicon oxycarbonitrides (SiOCN), or silicoboron carbonitrides (SiBCN). In some embodiments, the etch stop layer 106 may be formed using a CVD, PECVD, ALD, PVD, chemical solution deposition, or other like process. The etch stop layer 106 can be formed to a thickness of about 5 to 200 nm, although other thicknesses are within the contemplated scope of the disclosure.

In one embodiment, the etch stop layer 106 is patterned to expose one or more surfaces of the conductive line 102. The etch stop layer 106 may be patterned using, for example, a wet etch, a dry etch, or a combination thereof. In one embodiment, the etch stop layer 106 is patterned to provide one or more trenches. In one embodiment, these trenches are filled with conductive material to form one or more vias 108. In one embodiment, the conductive material may be overfilled into the trenches, forming overburdens above a surface of the etch stop layer 106. The overburden can be removed using, for example, chemical-mechanical planarization.

The vias 108 can be made of any suitable conducting material, such as, for example, metal (for example, tungsten, titanium, tantalum, ruthenium, zirconium, cobalt, copper, aluminum, lead, platinum, tin, silver, gold), conducting metallic compound materials (for example, tantalum nitride, titanium nitride, tantalum carbide, titanium carbide, titanium aluminum carbide, tungsten silicide, tungsten nitride, ruthenium oxide, cobalt silicide, nickel silicide), carbon nanotubes, conductive carbon, graphene, or any suitable combination of these materials. The conductive material can further include dopants that are incorporated during or after deposition. In one embodiment, the vias 108 can be copper or tungsten vias and can include a barrier metal liner (not depicted). A barrier metal liner prevents copper or tungsten from diffusing into, or doping, the surrounding materials, which can degrade their properties. Silicon, for example, forms deep-level traps when doped with copper. An ideal barrier metal liner must limit the bulk metal diffusivity sufficiently to chemically isolate the conductor from the surrounding materials and should have a high electrical conductivity, for example, tantalum, tantalum nitride, titanium, titanium nitride, cobalt, ruthenium, manganese, or titanium carbide.

In one embodiment, the semiconductor structure 100 can include an ILD 110 formed over the etch stop layer 106. The ILD 110 can be formed in a similar manner as the ILD 104, and can include any suitable dielectric material, such as, for example, silicon oxides, silicon nitrides, porous silicates, carbon doped oxides, silicon oxynitrides (SiON), spin-on polymers, and low permittivity (low-k) dielectric materials. In one embodiment, the ILD 110 can be deposited or otherwise formed to any desired thickness using PVD, CVD, PECVD, MOCVD, MBE, ALD, and/or spin-on dielectrics, and the like.

In one embodiment, the semiconductor structure 100 can include a gate 112 formed over a portion of the etch stop layer 106. In one embodiment, the gate 112 may be electrically coupled to the conductive line 102 through one of the vias 108. In one embodiment, the gate 112 is a high-k metal gate (HKMG) and can include a gate dielectric 114. In one embodiment, the gate dielectric 114 may be a high-k dielectric film. The gate 112 and the gate dielectric 114 are collectively referred to as a gate stack. In one embodiment, the gate stack also includes a work function metal (not depicted).

The gate 112 can include any suitable conductive material. Non-limiting examples of suitable conductive materials for the gate 112 include aluminum (Al), tantalum (Ta), cobalt (Co), nickel (Ni), palladium (Pd), platinum (Pt), gold (Au), silver (Ag), tungsten (W), titanium (Ti), molybdenum (Mo), germanium (Ge), ruthenium (Ru), a conducting metallic compound material (for example, tantalum nitride, titanium nitride, tantalum carbide, titanium carbide, titanium aluminum carbide, tungsten silicide, tungsten nitride, ruthenium oxide, cobalt silicide, nickel silicide), carbon nanotubes, conductive carbon, graphene, a silicide thereof, or any combination of the foregoing. The conductive material can further include dopants that are incorporated during or after deposition. The gate 112 can be deposited by any suitable deposition process, for example, CVD, PECVD, PVD, plating, thermal or e-beam evaporation, and sputtering. In one embodiment, the gate 112 may be formed by a lithographic patterning and reactive ion etching (RIE) of a bulk gate material (not illustrated). In some embodiments, the bulk gate material may be overfilled into a trench formed in the ILD 110. In one embodiment, the bulk gate material is then planarized using, for example, chemical-mechanical planarization. In one embodiment, the gate 112 can be used to tune a threshold voltage of the semiconductor structure 100. In one embodiment, the gate 112 can have a thickness of 5 nm to 100 nm or more, although other thicknesses are within the contemplated scope of the disclosure.

The gate dielectric 114 can include any suitable dielectric material. Non-limiting examples of suitable materials for the gate dielectric 114 include oxides, such as silicon dioxide, nitrides, such as silicon nitride, oxynitrides, silicates (for example, metal silicates), aluminates, titanates, or any combination thereof. In one embodiment, an electroglass (EG) can be used as the gate dielectric 114. In one embodiment, the gate dielectric 114 can include hexagonal boron nitride (HBN). In one embodiment, the gate dielectric 114 can include a dielectric material having a dielectric constant greater than, for example, 3.9, 7.0, or 10.0. Examples of high-k materials with a dielectric constant greater than 7.0 include, but are not limited to, metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The gate dielectric 114 can further include dopants such as, for example, lanthanum and aluminum. The gate dielectric 114 can be formed by any suitable deposition process, for example, using PVD, CVD, MOCVD, MBE, and/or ALD, and the like. In one embodiment, the gate dielectric 114 may be conformally formed over the exposed surface of the gate 112. The thickness of the gate dielectric 114 can vary depending on the deposition process as well as the composition and number of high-k dielectric materials used. In one embodiment, the gate dielectric 114 has a thickness in a range from about 0.5 to about 20 nm, with an example thickness of approximately 2 nm to approximately 4 nm, although other thicknesses are within the contemplated scope of the disclosure.

In one embodiment, a work function metal (not depicted) may be disposed between the gate dielectric 114 and the gate 112. Non-limiting examples of suitable materials for the work function metal include p-type work function metals (for example, ruthenium, palladium, platinum, cobalt, nickel, and conductive metal oxides, or any combination thereof) and n-type work function metals (for example, hafnium, zirconium, titanium, tantalum, aluminum, metal carbides, hafnium carbide, zirconium carbide, titanium carbide, and aluminum carbide, aluminides, or any combination thereof). In one embodiment, the work function metal can serve to modify the work function of the gate stack.

In one embodiment, the semiconductor structure 100 can include a semiconductor layer 116 (also referred to as a thin film transistor) formed over the gate dielectric 114 and the gate 112. The semiconductor layer 116 can be made of any suitable channel material, such as, for example, monocrystalline silicon, polysilicon, silicon germanium, carbon doped silicon, III-V compound semiconductor, II-VI compound semiconductor, indium phosphide (InP), indium arsenide (InAs), indium gallium arsenide (InGaAs), gallium nitride (GaN), gallium arsenide antimonide (GaAsSb), indium oxide (In₂O₃), gallium oxide (Ga₂O₃), cuprous oxide, tin oxide, indium tin oxide, indium gallium tin oxide, indium zinc oxide, nickel oxide, molybdenum disulfide, tungsten disulfide, black phosphorus, cuprous sulfide, cuprous selenide, amorphous semiconductors such as zinc oxide (ZnO), indium gallium zinc oxide (IGZO), amorphous silicon (a-Si), amorphous germanium (a-Ge), polycrystalline germanium, polycrystalline silicon, and/or polycrystalline InGaAs, and the like.

The semiconductor layer 116 can be formed by any suitable deposition process, for example, using PVD, CVD, MOCVD, MBE, and/or ALD, and the like. In one embodiment, the ILD 110 is patterned to expose a surface of the gate dielectric 114 and the semiconductor layer 116 is conformally formed over the exposed surface of the gate dielectric 114. The semiconductor layer 116 can be deposited or otherwise formed to any desired thickness. In one embodiment, the semiconductor layer 116 can have a thickness of 3 nm to 100 nm or more, for example, 5 nm to 20 nm, although other thicknesses are within the contemplated scope of the disclosure.

In one embodiment, the semiconductor structure 100 can include a source 118 (also referred to as a first diode terminal) and a drain 120 formed over portions of the semiconductor layer 116. In one embodiment, the source 118 and the drain 120 are formed over opposite ends of the semiconductor layer 116. The source 118 and the drain 120 can be made of, for example, tungsten, although any suitable conductive material can be used. Non-limiting examples of suitable conductive materials for the source 118 and the drain 120 include aluminum (Al), tantalum (Ta), cobalt (Co), nickel (Ni), palladium (Pd), platinum (Pt), gold (Au), silver (Ag), tungsten (W), titanium (Ti), molybdenum (Mo), germanium (Ge), ruthenium (Ru), a conducting metallic compound material (for example, tantalum nitride, titanium nitride, tantalum carbide, titanium carbide, titanium aluminum carbide, tungsten silicide, tungsten nitride, ruthenium oxide, cobalt silicide, nickel silicide), carbon nanotubes, conductive carbon, graphene, a silicide thereof, or any combination of the foregoing.

The source 118 and a drain 120 can be deposited using any suitable deposition process, for example, CVD, PECVD, PVD, plating, thermal or e-beam evaporation, and sputtering. In one embodiment, the source 118 and a drain 120 may be formed by a lithographic patterning and RIE of a bulk conductive material (not illustrated). In some embodiments, the bulk gate material may be overfilled into separate trenchs formed in the ILD 110. In one embodiment, the bulk gate material is then planarized using, for example, chemical-mechanical planarization, to form the source 118 and a drain 120. The source 118 and a drain 120 can each have a thickness of 5 nm to 100 nm or more, although other thicknesses are within the contemplated scope of the disclosure.

In one embodiment, the semiconductor structure 100 can include a capping layer 122 (also referred to as a barrier liner) formed over portions of the semiconductor layer 116. In one embodiment, the capping layer 122 is formed between the source 118 and the drain 120. The capping layer 122 serves to passivate the top surface of the semiconductor layer 116. The capping layer 122 can be made of any suitable material, such as, for example, tantalum, tantalum nitride, titanium, titanium nitride, cobalt, ruthenium, manganese, or titanium carbide, although other materials are within the contemplated scope of the disclosure. The capping layer 122 can be deposited using any suitable deposition process, for example, CVD, PECVD, PVD, plating, thermal or e-beam evaporation, and sputtering. The capping layer 122 can have a thickness of 5 nm to 100 nm or more, although other thicknesses are within the contemplated scope of the disclosure.

In one embodiment, the semiconductor structure 100 can include a conductive region 124 (also referred to as a second diode terminal). In one embodiment, a first portion of the conductive region 124 is electrically coupled to the drain 120 through one or more of the vias 108, while a second portion of the conductive region 124 is electrically coupled to the conductive line 102 through one or more of the other vias 108. In this manner, the conductive region 124 serves to electrically short the drain 120 to the conductive line 102.

The conductive region 124 can be made of, for example, tungsten, although any suitable conductive material can be used. Non-limiting examples of suitable conductive materials for the conductive region 124 include aluminum (Al), tantalum (Ta), cobalt (Co), nickel (Ni), palladium (Pd), platinum (Pt), gold (Au), silver (Ag), tungsten (W), titanium (Ti), molybdenum (Mo), germanium (Ge), ruthenium (Ru), a conducting metallic compound material (for example, tantalum nitride, titanium nitride, tantalum carbide, titanium carbide, titanium aluminum carbide, tungsten silicide, tungsten nitride, ruthenium oxide, cobalt silicide, nickel silicide), carbon nanotubes, conductive carbon, graphene, a silicide thereof, or any combination of the foregoing.

The conductive region 124 can be deposited using any suitable deposition process, for example, CVD, PECVD, PVD, plating, thermal or e-beam evaporation, and sputtering. In one embodiment, the conductive region 124 may be formed by a lithographic patterning and RIE of a bulk conductive material (not illustrated). In some embodiments, the bulk gate material may be overfilled into a trench formed in the ILD 110. In one embodiment, the bulk gate material is then planarized using, for example, chemical-mechanical planarization, to form the conductive region 124. The conductive region 124 can have a thickness of 5 nm to 100 nm or more, although other thicknesses are within the contemplated scope of the disclosure.

In some embodiments, the semiconductor structure 100 can include a conductive region 126. The conductive region 126 serves in part to reduce the required aspect ratio of the vias which electrically couple the conductive region 124 to the conductive line 102. In other words, the conductive region 126 allows for two vias having relatively small aspect ratios rather than a single via having a large aspect ratio.

The conductive region 126 can be made of, for example, tungsten, although any suitable conductive material can be used. Non-limiting examples of suitable conductive materials for the conductive region 126 include aluminum (Al), tantalum (Ta), cobalt (Co), nickel (Ni), palladium (Pd), platinum (Pt), gold (Au), silver (Ag), tungsten (W), titanium (Ti), molybdenum (Mo), germanium (Ge), ruthenium (Ru), a conducting metallic compound material (for example, tantalum nitride, titanium nitride, tantalum carbide, titanium carbide, titanium aluminum carbide, tungsten silicide, tungsten nitride, ruthenium oxide, cobalt silicide, nickel silicide), carbon nanotubes, conductive carbon, graphene, a silicide thereof, or any combination of the foregoing.

The conductive region 126 can be deposited using any suitable deposition process, for example, CVD, PECVD, PVD, plating, thermal or e-beam evaporation, and sputtering. In one embodiment, the conductive region 126 may be formed by a lithographic patterning and RIE of a bulk conductive material (not illustrated). In some embodiments, the bulk gate material may be overfilled into a trench formed in the ILD 110. In one embodiment, the bulk gate material is then planarized using, for example, chemical-mechanical planarization, to form the conductive region 126. The conductive region 124 can have a thickness of 5 nm to 100 nm or more, although other thicknesses are within the contemplated scope of the disclosure.

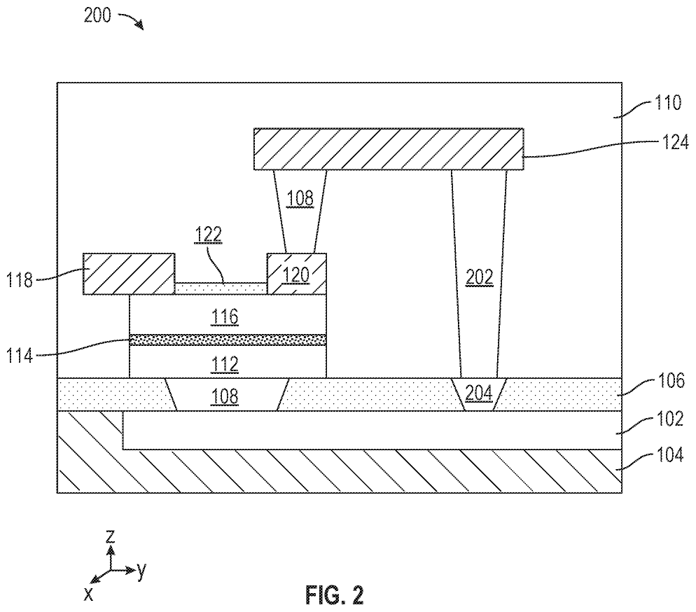

FIG. 2 depicts a cross-sectional view of a semiconductor structure 200 during the fabrication of bandgap reference diodes using thin film transistors in accordance with one or more example embodiments of the disclosure. The semiconductor structure 200 is formed in a similar manner as the semiconductor structure 100, except that the semiconductor structure 200 does not include the conductive region 126 (as depicted in FIG. 1). Instead, the conductive region 124 is electrically coupled to the conductive line 102 through a high aspect ratio via 202. The high aspect ratio via 202 can be formed using similar materials as the vias 108, such as, for example, metal (for example, tungsten, titanium, tantalum, ruthenium, zirconium, cobalt, copper, aluminum, lead, platinum, tin, silver, gold), conducting metallic compound materials (for example, tantalum nitride, titanium nitride, tantalum carbide, titanium carbide, titanium aluminum carbide, tungsten silicide, tungsten nitride, ruthenium oxide, cobalt silicide, nickel silicide), carbon nanotubes, conductive carbon, graphene, or any suitable combination of these materials. In one embodiment, the high aspect ratio via 202 is formed by patterning a trench in the ILD 110. The trench can be overfilled with conductive material, and planarized, in a similar manner as the vias 108, as discussed previously herein. In one embodiment, the high aspect ratio via 202 is formed after patterning a trench in the etch stop layer 106. In one embodiment, the trench is filled with conductive material to form a via 204, and the high aspect ratio via 202 is formed between the conductive region 124 and the via 204.

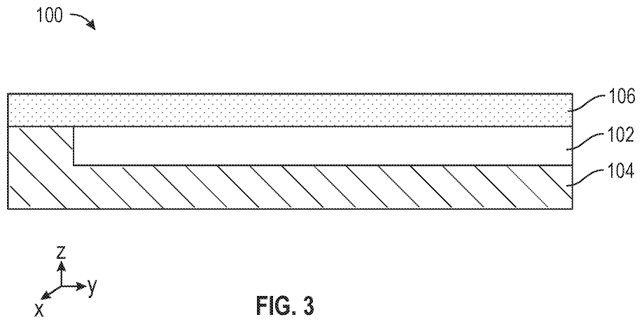

FIG. 3 depicts a cross-sectional view of the semiconductor structure 100 depicted in FIG. 1 during an intermediate process operation in accordance with one or more example embodiments of the disclosure. As depicted in FIG. 3, the semiconductor structure 100 can include a conductive line 102 (also known as an interconnect or as a metal line) formed in an ILD 104 of a metallization layer (not depicted). The metallization layer can be a first metallization layer, or any other metallization layer, of a BEOL workflow. As described previously herein, the conductive line 102 can be formed and patterned using known metallization techniques. In one embodiment, the ILD 104 may be patterned using, for example, a wet etch, a dry etch, or a combination thereof, to provide one or more trenches. In one embodiment, these trenches are filled with conductive material to form the conductive line 102. In one embodiment, the conductive material may be overfilled into the trenches, forming overburdens above a surface of the ILD 104. The overburden can be removed using, for example, chemical-mechanical planarization.

In one embodiment, the semiconductor structure 100 can include an etch stop layer 106 formed over the conductive line 102 and the ILD 104. The etch stop layer 106 can be made of any suitable material, such as, for example, a low-k dielectric, silicon nitride, SiON, silicon oxycarbonitrides (SiOCN), or silicoboron carbonitrides (SiBCN). In some embodiments, the etch stop layer 106 is conformally deposited over the conductive line 102, using any suitable process. The etch stop layer 106 can be formed to a thickness of about 5 to 200 nm, although other thicknesses are within the contemplated scope of the disclosure.

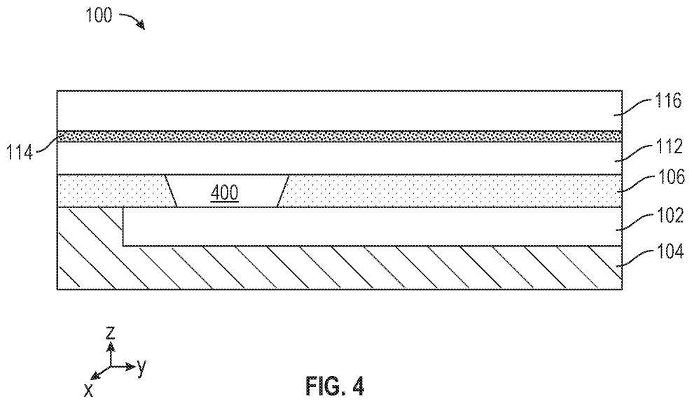

FIG. 4 depicts a cross-sectional view of the semiconductor structure 100 depicted in FIG. 1 during an intermediate process operation in accordance with one or more example embodiments of the disclosure. As depicted in FIG. 4, the etch stop layer 106 is patterned to provide a trench. In one embodiment, the trench is filled with conductive material to form a via 400. In one embodiment, the gate 112 is conformally deposited over the etch stop layer 106 and the via 400 to a thickness of 5 nm to 100 nm or more, although other thicknesses are within the contemplated scope of the disclosure. In one embodiment, the gate dielectric 114 is conformally deposited over the gate 112 to a thickness of about 0.5 to about 20 nm, with an example thickness of approximately 2 nm to approximately 4 nm, although other thicknesses are within the contemplated scope of the disclosure. In one embodiment, after forming the gate 112 and gate dielectric 114, the semiconductor layer 116 is conformally deposited to a thickness of 3 nm to 100 nm or more, for example, 5 nm to 20 nm, although other thicknesses are within the contemplated scope of the disclosure.

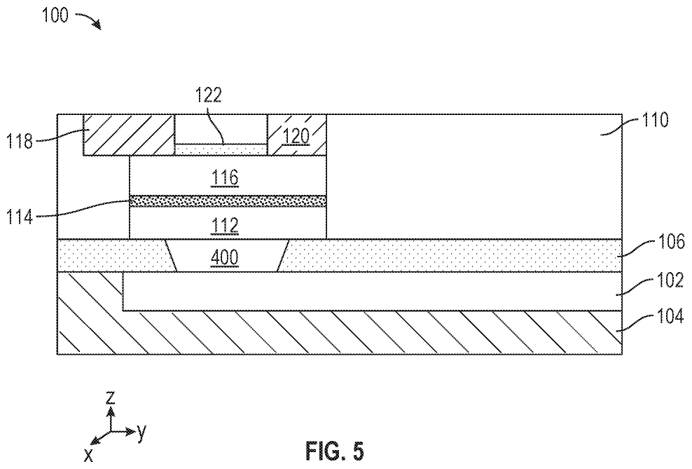

FIG. 5 depicts a cross-sectional view of the semiconductor structure 100 depicted in FIG. 1 during an intermediate process operation in accordance with one or more example embodiments of the disclosure. As depicted in FIG. 5, the gate 112, gate dielectric 114, and semiconductor layer 116 are patterned to form a stack over the via 400 and the etch stop layer 106. The gate 112, gate dielectric 114, and semiconductor layer 116 may be patterned using, for example, a wet etch, a dry etch, or a combination of sequential wet or dry etches. In one embodiment, the gate 112, gate dielectric 114, and semiconductor layer 116 are sequentially patterned using one or more RIEs selective to the etch stop layer 106.

After patterning the gate 112, gate dielectric 114, and semiconductor layer 116, the ILD 110 is deposited over the semiconductor structure 100. In one embodiment, the ILD 110 can be deposited or otherwise formed to any desired thickness using PVD, CVD, PECVD, MOCVD, MBE, ALD, and/or spin-on dielectrics, and the like. The ILD 110 is then patterned to form one or more trenches for the source 118 and the drain 120.

In one embodiment, the source 118 and the drain 120 are formed over opposite ends of the semiconductor layer 116. In one or more embodiments, the source 118, the drain 120, or both extend past a sidewall of the semiconductor layer 116. In other embodiments, the source 118 and the drain 120 are coplanar to sidewalls of the semiconductor layer 116. The source 118 and the drain 120 can be deposited using any suitable deposition process, for example, CVD, PECVD, PVD, plating, thermal or e-beam evaporation, and sputtering. In some embodiments, the source 118 and a drain 120 are formed by depositing a bulk conductive material (not illustrated) over the semiconductor layer 116. The bulk conductive material is then patterned by removing a portion of the bulk conductive material to expose a surface of the semiconductor layer 116 between the source 118 and the drain 120. In other embodiments, the bulk gate material may be overfilled into separate trenches formed in the ILD 110. In one embodiment, the bulk gate material is then planarized using, for example, chemical-mechanical planarization, to form the source 118 and a drain 120. The source 118 and a drain 120 can each have a thickness of 5 nm to 100 nm or more, although other thicknesses are within the contemplated scope of the disclosure.

In one embodiment, a capping layer 122 (also referred to as a barrier liner) is formed on a surface of the semiconductor layer 116 between the source 118 and the drain 120. The capping layer 122 serves to passivate the top surface of the semiconductor layer 116. The capping layer 122 can be made of any suitable material, such as, for example, tantalum, tantalum nitride, titanium, titanium nitride, cobalt, ruthenium, manganese, or titanium carbide, although other materials are within the contemplated scope of the disclosure. The capping layer 122 can be deposited using any suitable deposition process, for example, CVD, PECVD, PVD, plating, thermal or e-beam evaporation, and sputtering. The capping layer 122 can have a thickness of 5 nm to 100 nm or more, although other thicknesses are within the contemplated scope of the disclosure.

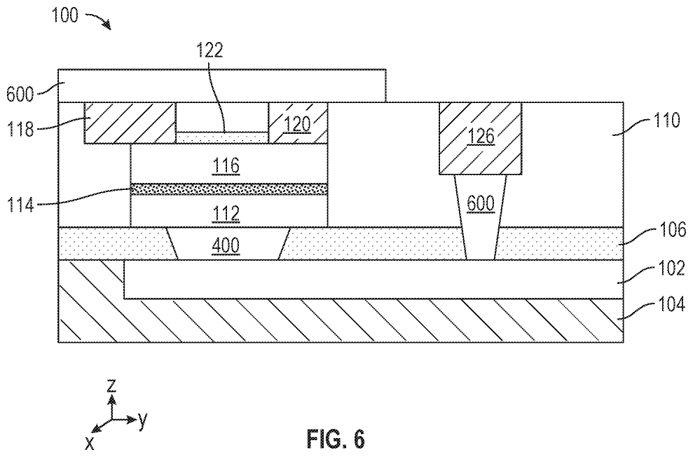

FIG. 6 depicts a cross-sectional view of the semiconductor structure 100 depicted in FIG. 1 during an intermediate process operation in accordance with one or more example embodiments of the disclosure. As depicted in FIG. 6, in one embodiment a hard mask 600 can be formed over the source 118 and the drain 120. The hard mask 600 can be made of any suitable hard mask material, such as, for example, silicon nitride, silicon oxynitrides, silicon oxycarbonitrides, or silicoboron carbonitrides. The hard mask 600 can be deposited or otherwise formed to any desired thickness using PVD, CVD, PECVD,

MOCVD, MBE, ALD, and/or spin-on dielectrics, and the like.

In one embodiment, portions of the ILD 110 and etch stop layer 106 are removed to form a trench exposing a surface of the conductive line 102 after forming the hard mask 600. The ILD 110 and etch stop layer 106 may be patterned using, for example, a wet etch, a dry etch, or a combination of sequential wet or dry etches. In one embodiment, the ILD 110 and etch stop layer 106 are sequentially patterned using one or more RIEs. In one embodiment, the etch stop layer 106 is patterned using a timed RIE or a RIE selective to the conductive line 102.

In one embodiment, the trench is filled with conductive material to form a via 600 and the conductive region 126. The via 600 and conductive region 126 can be formed using any suitable conductive material. The via 600 and the conductive region 126 can be formed using a same, or different, conductive material. In one embodiment, the conductive region 126 is deposited over the via 600 such that an overburden forms above a surface of the ILD 110. In one embodiment, the hard mask 600 is removed and the conductive region 126 is planarized to a surface of the source 118 or the drain 120 using, for example, chemical-mechanical planarization. The conductive region 124 can have a thickness of 5 nm to 100 nm or more, although other thicknesses are within the contemplated scope of the disclosure.

After forming the conductive region 124, the ILD 110 can be refilled with additional dielectric material to any desired thickness. In some embodiments, the ILD 110 is refilled and then patterned to form one or more trenches. These trenches can be filled to form the remaining vias 108 depicted in FIG. 1 and this process (ILD refill, ILD pattern, conductive fill) can be repeated to form the conductive region 124.

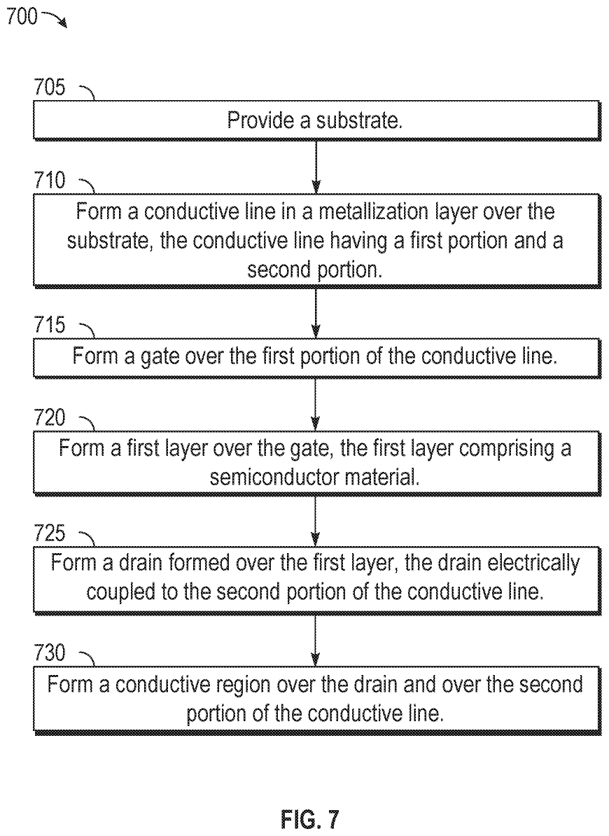

FIG. 7 shows a diagram of an example flow diagram for the fabrication of bandgap reference diodes using thin film transistors, in accordance with example embodiments of the disclosure. In block 705, a substrate can be provided. In one embodiment, the substrate can refer to a solid (usually planar) substance onto which a layer of another substance is applied, and to which that second substance adheres.

In block 710, a conductive line is formed in a metallization layer over the substrate. The conductive line includes a first portion and a second portion. The conductive line can be formed in a similar manner as the conductive line 102 discussed previously herein.

In block 715, a gate is formed over the first portion of the conductive line. The gate can be formed in a similar manner as the gate 112 discussed previously herein.

In block 720, a first layer is formed over the gate. In some embodiments, the first layer is a thin film transistor formed in a similar manner as the semiconductor layer 116 discussed previously herein. In some embodiments, the first layer includes semiconductor material such as, for example, monocrystalline silicon, polysilicon, silicon germanium, carbon doped silicon, III-V compound semiconductor, II-VI compound semiconductor, and the like.

In block 725, a drain is formed over the first layer. The drain can be formed in a similar manner as the drain 120 discussed previously herein. The drain is electrically coupled to the second portion of the conductive line. In some embodiments, the drain is electrically coupled to the second portion of the conductive line through one or more vias and one or more conductive regions (as depicted in FIGS. 1 and 2).

In block 730, a conductive region is formed over the drain. The conductive region can be formed in a similar manner as the conductive region 124 discussed previously herein. In some embodiments, a first portion of the conductive region is electrically coupled to the drain and a second portion of the conductive region is electrically coupled to the second portion of the conductive line.

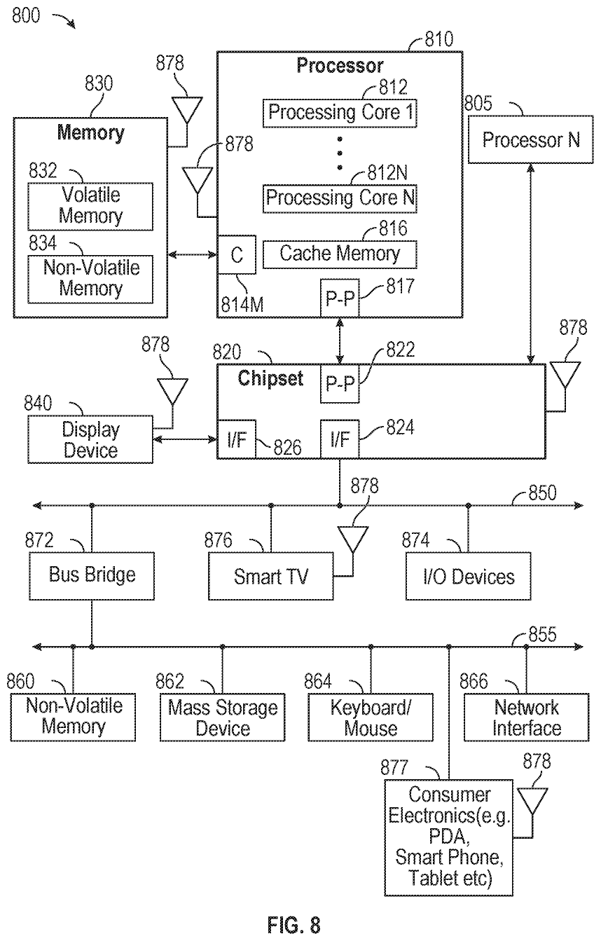

FIG. 8 depicts an example of a system 800 according to one or more embodiments of the disclosure. In one embodiment, the bandgap reference diodes comprised of thin film transistors as described herein can be used in connection with or formed as a part of any of the devices shown in system 800. In one embodiment, system 800 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 800 can include a system on a chip (SOC) system.

In one embodiment, system 800 includes multiple processors including processor 810 and processor N 805, where processor N 805 has logic similar or identical to the logic of processor 810. In one embodiment, processor 810 has one or more processing cores (represented here by processing core 1 812 and processing core N 812N, where 812N represents the Nth processor core inside processor 810, where N is a positive integer). More processing cores can be present (but not depicted in the diagram of FIG. 8). In some embodiments, processor core 812 includes, but is not limited to, pre-fetch logic to fetch instructions, decode logic to decode the instructions, execution logic to execute instructions, a combination thereof, or the like. In some embodiments, processor 810 has a cache memory 816 to cache instructions and/or data for system 800. Cache memory 816 may be organized into a hierarchical structure including one or more levels of cache memory.

In some embodiments, processor 810 includes a memory controller (MC) 814, which is configured to perform functions that enable the processor 810 to access and communicate with memory 830 that includes a volatile memory 832 and/or a non-volatile memory 834. In some embodiments, processor 810 can be coupled with memory 830 and chipset 820. Processor 810 may also be coupled to a wireless antenna 877 to communicate with any device configured to transmit and/or receive wireless signals. In one embodiment, the wireless antenna 877 operates in accordance with, but is not limited to, the IEEE 1102.11 standard and its related family, Home Plug AV (HPAV), Ultra Wide Band (UWB), Bluetooth, WiMax, or any form of wireless communication protocol.

In some embodiments, volatile memory 832 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 834 includes, but is not limited to, flash memory, phase change memory (PCM), read-only memory (ROM), electrically erasable programmable read-only memory (EEPROM), or any other type of non-volatile memory device.

Memory device 830 stores information and instructions to be executed by processor 810. In one embodiment, memory 830 may also store temporary variables or other intermediate information while processor 810 is executing instructions. In the illustrated embodiment, chipset 820 connects with processor 810 via Point-to-Point (PtP or P-P) interface 817 and P-P interface 822. Chipset 820 enables processor 810 to connect to other elements in system 800. In some embodiments of the disclosure, P-P interface 817 and P-P interface 822 can operate in accordance with a PtP communication protocol, such as the Intel® QuickPath Interconnect (QPI) or the like. In other embodiments, a different interconnect may be used.

In some embodiments, chipset 820 can be configured to communicate with processor 810, the processor N 805, display device 840, and other devices 872, 876, 874, 860, 862, 864, 866, 877, etc. Chipset 820 may also be coupled to the wireless antenna 877 to communicate with any device configured to transmit and/or receive wireless signals.

Chipset 820 connects to display device 840 via interface 826. Display 840 may be, for example, a liquid crystal display (LCD), a plasma display, cathode ray tube (CRT) display, or any other form of visual display device. In some embodiments of the disclosure, processor 810 and chipset 820 are integrated into a single SOC. In addition, chipset 820 connects to bus 850 and/or bus 855 that interconnect various elements 874, 860, 862, 864, and 866. Bus 850 and bus 855 may be interconnected via a bus bridge 872. In one embodiment, chipset 820 couples with a non-volatile memory 860, a mass storage device(s) 862, a keyboard/mouse 864, and a network interface 866 via interface 824 and/or 826, smart TV 876, consumer electronics 877, etc.

In one embodiment, mass storage device(s) 862 can include, but not be limited to, a solid state drive, a hard disk drive, a universal serial bus flash memory drive, or any other form of computer data storage medium. In one embodiment, network interface 866 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 702.11 standard and its related family, Home Plug AV (HPAV), Ultra Wide Band (UWB), Bluetooth, WiMax, or any form of wireless communication protocol.

While the modules shown in FIG. 8 are depicted as separate blocks within the system 800, the functions performed by some of these blocks may be integrated within a single semiconductor circuit or may be implemented using two or more separate integrated circuits. For example, although cache memory 816 is depicted as a separate block within processor 810, cache memory 816 or selected elements thereof can be incorporated into processor core 812.

It is noted that the system 800 described herein may include any suitable type of microelectronics packaging and configurations thereof, including, for example, system in a package (SiP), system on a package (SOP), package on package (PoP), interposer package, 3D stacked package, etc. Further, any suitable type of microelectronic components may be provided in the semiconductor packages, as described herein. For example, microcontrollers, microprocessors, baseband processors, digital signal processors, memory dies, field gate arrays, logic gate dies, passive component dies, MEMSs, surface mount devices, application specific integrated circuits, baseband processors, amplifiers, filters, combinations thereof, or the like may be packaged in the semiconductor packages, as disclosed herein. The semiconductor devices (for example, the semiconductor devices described in connection with any of FIGS. 1-6), as disclosed herein, may be provided in any variety of electronic devices including consumer, industrial, military, communications, infrastructural, and/or other electronic devices.

In various embodiments, the devices, as described herein, may be used in connection with one or more processors. The one or more processors may include, without limitation, a central processing unit (CPU), a digital signal processor(s) (DSP), a reduced instruction set computer (RISC), a complex instruction set computer (CISC), a microprocessor, a microcontroller, a field programmable gate array (FPGA), or any combination thereof. The processors may also include one or more application specific integrated circuits (ASICs) or application specific standard products (ASSPs) for handling specific data processing functions or tasks. In certain embodiments, the processors may be based on an Intel® Architecture system and the one or more processors and any chipset included in an electronic device may be from a family of Intel® processors and chipsets, such as the Intel® Atom® processor(s) family or Intel-64 processors (for example, Sandy Bridge®, Ivy Bridge®, Haswell®, Broadwell®, Skylake®, etc.).

Additionally or alternatively, the devices, as described herein, may be used in connection with one or more additional memory chips. The memory may include one or more volatile and/or non-volatile memory devices including, but not limited to, magnetic storage devices, read-only memory (ROM), random access memory (RAM), dynamic RAM (DRAM), static RAM (SRAM), synchronous dynamic RAM (SDRAM), double data rate (DDR) SDRAM (DDR-SDRAM), RAM-BUS DRAM (RDRAM), flash memory devices, electrically erasable programmable read-only memory (EEPROM), non-volatile RAM (NVRAM), universal serial bus (USB) removable memory, or combinations thereof.

In example embodiments, the electronic device in which the disclosed devices are used and/or provided may be a computing device. Such a computing device may house one or more boards on which the devices may be disposed. The board may include a number of components including, but not limited to, a processor and/or at least one communication chip. The processor may be physically and electrically connected to the board through, for example, electrical connections of the devices. The computing device may further include a plurality of communication chips. For instance, a first communication chip may be dedicated to shorter range wireless communications such as Wi-Fi and Bluetooth, and a second communication chip may be dedicated to longer range wireless communications such as GPS, EDGE, GPRS, CDMA, WiMAX, LTE, EV-DO, and others. In various example embodiments, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, combinations thereof, or the like. In further example embodiments, the computing device may be any other electronic device that processes data.

Example 1 may include an interconnect structure for an integrated circuit, the interconnect structure comprising: a conductive line of a metallization layer, the conductive line having a first portion and a second portion; a gate over the first portion of the conductive line; a first layer over the gate, the first layer comprising a semiconductor material; and a drain formed over the first layer, the drain electrically coupled to the second portion of the conductive line.

Example 2 may include the structure of example 1 and/or some other example herein, wherein the first layer comprises a thin film transistor.

Example 3 may include the structure of example 1 and/or some other example herein, wherein the drain is on a first portion of the first layer, and wherein the structure further comprises a source on a second portion of the first layer.

Example 4 may include the structure of example 3 and/or some other example herein, further comprising a third layer between the source and the drain.

Example 5 may include the structure of example 1 and/or some other example herein, further comprising a conductive region over the drain and over the second portion of the conductive line.

Example 6 may include the structure of example 5 and/or some other example herein, wherein the conductive region comprises a first portion and a second portion, the first portion of the conductive region electrically coupled to the drain, and the second portion of the conductive region electrically coupled to the second portion of the conductive line.

Example 7 may include the structure of example 1 and/or some other example herein, further comprising a gate dielectric between the gate and the first layer.

Example 8 may include the structure of example 1 and/or some other example herein, wherein the metallization layer comprises a first metallization layer formed over a substrate during a back-end-of-line (BEOL) workflow.

Example 9 may include the structure of example 8 and/or some other example herein, further comprising one or more second metallization layers between the first metallization layer and the substrate.

Example 10 may include an integrated circuit (IC) device, the device comprising: a conductive line of a metallization layer, the conductive line having a first portion and a second portion; a gate over the first portion of the conductive line; a thin film transistor over the gate, the thin film transistor comprising a semiconductor material; and a drain formed over the thin film transistor, the drain electrically coupled to the second portion of the conductive line.

Example 11 may include the device of claim 10 and/or some other example herein, wherein the drain is on a first portion of the thin film transistor, and wherein the structure further comprises a source on a second portion of the thin film transistor.

Example 12 may include the device of claim 11 and/or some other example herein, further comprising a first layer between the source and the drain.

Example 13 may include the device of claim 10 and/or some other example herein, further comprising a conductive region over the drain and over the second portion of the conductive line.

Example 14 may include the device of claim 13 and/or some other example herein, wherein the conductive region comprises a first portion and a second portion, the first portion of the conductive region electrically coupled to the drain, and the second portion of the conductive region electrically coupled to the second portion of the conductive line.

Example 15 may include the device of claim 10 and/or some other example herein, further comprising a gate dielectric between the gate and the thin film transistor.

Example 16 may include the device of claim 10 and/or some other example herein, wherein the metallization layer comprises a first metallization layer, and wherein the device further comprises one or more second metallization layers between the first metallization layer and a substrate.

Example 17 may include a method for fabricating an interconnect structure for an integrated circuit, the method comprising: forming a conductive line in a metallization layer, the conductive line having a first portion and a second portion; forming a gate over the first portion of the conductive line; forming a first layer over the gate, the first layer comprising a semiconductor material; and forming a drain formed over the first layer, the drain electrically coupled to the second portion of the conductive line.

Example 18 may include the method of claim 17 and/or some other example herein, further comprising forming a conductive region over the drain and over the second portion of the conductive line.

Example 19 may include the method of claim 18 and/or some other example herein, further comprising electrically coupling a first portion of the conductive region to the drain and electrically coupling a second portion of the conductive region to the second portion of the conductive line.

Example 20 may include the method of claim 17 and/or some other example herein, wherein the metallization layer comprises a first metallization layer, and the method further comprises forming one or more second metallization layers between the first metallization layer and a substrate.

Various features, aspects, and embodiments have been described herein. The features, aspects, and embodiments are susceptible to combination with one another as well as to variation and modification, as will be understood by those having skill in the art. The present disclosure should, therefore, be considered to encompass such combinations, variations, and modifications.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Other modifications, variations, and alternatives are also possible. Accordingly, the claims are intended to cover all such equivalents.

While the disclosure includes various embodiments, including at least a best mode, it is to be understood that many alternatives, modifications, and variations will be apparent to those skilled in the art in light of the foregoing description. Accordingly, the disclosure is intended to embrace all such alternatives, modifications, and variations, which fall within the scope of the included claims. All matters disclosed herein or shown in the accompanying drawings are to be interpreted in an illustrative and non-limiting sense.

This written description uses examples to disclose certain embodiments of the disclosure, including the best mode, and also to enable any person skilled in the art to practice certain embodiments of the disclosure, including making and using any apparatus, devices or systems and performing any incorporated methods and processes. The patentable scope of certain embodiments of the disclosure is defined in the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

1. An interconnect structure for an integrated circuit, the interconnect structure comprising:
a conductive line of a metallization layer, the conductive line comprising a first portion and a second portion;
a gate over the first portion of the conductive line;
a first layer over the gate, the first layer comprising a semiconductor material; and
a drain over the first layer, the drain electrically coupled to the second portion of the conductive line.

2. The structure of claim 1, wherein the first layer comprises a thin film transistor.

3. The structure of claim 1, wherein the drain is on a first portion of the first layer, and wherein the structure further comprises a source on a second portion of the first layer.

4. The structure of claim 3, further comprising a third layer between the source and the drain.

5. The structure of claim 1, further comprising a conductive region over the drain and over the second portion of the conductive line.

6. The structure of claim 5, wherein the conductive region comprises a first portion and a second portion, the first portion of the conductive region electrically coupled to the drain, and the second portion of the conductive region electrically coupled to the second portion of the conductive line.

7. The structure of claim 1, further comprising a gate dielectric between the gate and the first layer.

8. The structure of claim 1, wherein the metallization layer comprises a first metallization layer over a substrate in a back-end-of-line (BEOL) workflow.

9. The structure of claim 8, further comprising one or more second metallization layers between the first metallization layer and the substrate.

10. An integrated circuit (IC) device comprising:
a conductive line of a metallization layer, the conductive line comprising a first portion and a second portion;
a gate over the first portion of the conductive line;
a thin film transistor over the gate, the thin film transistor comprising a semiconductor material; and
a drain over the thin film transistor, the drain electrically coupled to the second portion of the conductive line.

11. The device of claim 10, wherein the drain is on a first portion of the thin film transistor, and wherein the structure further comprises a source on a second portion of the thin film transistor.

12. The device of claim 11, further comprising a first layer between the source and the drain.

13. The device of claim 10, further comprising a conductive region over the drain and over the second portion of the conductive line.

14. The device of claim 13, wherein the conductive region comprises a first portion and a second portion, the first portion of the conductive region electrically coupled to the drain, and the second portion of the conductive region electrically coupled to the second portion of the conductive line.

15. The device of claim 10, further comprising a gate dielectric between the gate and the thin film transistor.

16. The device of claim 10, wherein the metallization layer comprises a first metallization layer, and wherein the device further comprises one or more second metallization layers between the first metallization layer and a substrate.

17. A method for fabricating an interconnect structure for an integrated circuit, the method comprising:
forming a conductive line in a metallization layer, the conductive line comprising a first portion and a second portion;
forming a gate over the first portion of the conductive line;
forming a first layer over the gate, the first layer comprising a semiconductor material; and
forming a drain over the first layer, the drain electrically coupled to the second portion of the conductive line.

18. The method of claim 17, further comprising forming a conductive region over the drain and over the second portion of the conductive line.

19. The method of claim 18, further comprising electrically coupling a first portion of the conductive region to the drain and electrically coupling a second portion of the conductive region to the second portion of the conductive line.

20. The method of claim 17, wherein the metallization layer comprises a first metallization layer, and the method further comprises forming one or more second metallization layers between the first metallization layer and a substrate.
